(19) United States
(12) Patent Application Publication
(10) Pub. No.: US 2002/0062555 A1
(43) Pub. Date: May 30, 2002

(54) Surface mounting device and method thereof

(75) Inventors: Ji Hyun Hwang, Kyungki-do (KR); Do Hyun Kim, Kyoungki-do (KR)

Correspondence Address: FLESHNER & KIM, LLP, P.O. Box 221200, Chantilly, VA, 20153-1200, US

(73) Assignee: MIRAE Corporation

(21) Appl. No.: 09/988,296

(22) Filed: Nov. 19, 2001

(30) Foreign Application Priority Data
Nov. 24, 2000 (KR) 2000-70453

(51) Int. Cl. H05K 3/30

(52) U.S. Cl. 29/832

(57) ABSTRACT

The surface mounting device includes: multiple conveyers installed at a predetermined position of a base frame and carrying a printed circuit board(PCB) to a parts mounting work position or discharging the PCB on which parts have been mounted, so that they can be moved in the X and Y-axis directions by a X-Y gantry installed on the base frame and can absorb parts supplied from a parts supply unit and the parts can be mounted by a head unit mounting the adsorbed parts on the PCB; and multiple multi-layer transfer units each installed at both ends of the conveyers and carrying the PCB to the PCB conveyers or loading the discharged PCB. The transfer speed of PCB is improved.

### BACKGROUND OF THE INVENTION

1. Field of the Invention

The present invention relates to a surface mounting device and a method thereof, and more particularly, to a surface mounting device and a method thereof for enhancing a parts mounting speed by improving a speed for supplying a printed circuit board to a parts mounting work position or for discharging the printed circuit board on which parts have been mounted.

2. Description of the Related Art

The construction of a conventional surface mounting device will now be explained with reference to FIGS. 1 and 2. FIG. 1 is a perspective view of a surface mounting device according to the conventional art. FIG. 2 is a plane view of a surface mounting device schematically showing the internal construction of the surface mounting device as illustrated in FIG. 1. As illustrated therein, the surface mounting device includes a base frame 1, X and Y gantries 2 and 3, a conveyer 4, a parts supply unit 5 and a head unit 6.

The head unit 6 is driven in the X-axis direction by a X-axis motor 2a and a X-axis ball screw 2b each installed at the X and Y gantries 2 and 3 installed on the top surface of the base frame 1 and is driven in the Y-axis direction by a Y-axis motor 3a and a Y-axis ball screw 3b, for thereby performing a vacuum-absorbing of parts supplied from the parts supply unit 5 and mounting the same on a printed circuit board (P). The printed circuit board (P) on which parts are mounted is carried to the conveyer 4 installed on the base frame 1 through a printed circuit board inlet 4a and then is carried to a parts mounting work position.

Afterwards, when parts has been mounted by the head unit 6 in the stop state, the printed circuit board (P) is discharged through a printed circuit board outlet 4b by the conveyer 4. Here, the parts mounted on the printed circuit board (P) are supplied by a tape feeder 5a installed at the parts supply unit 5. The tape feeder 5a is installed by moving a tape wheel 5b containing parts by a wheel moving device 5c. When the tape wheel 5b is installed at the tape feeder 5a, the tape feeder 5a supplies parts at a predetermined pitch so that the head unit 6 can continuously perform a vacuum-absorbing of the parts contained in the tape wheel 5b and can mount them on the printed circuit board (P).

As described above, in a case in which the printed circuit board is sequentially carried to the parts mounting work position one by one by the conveyer and then is discharged as the parts are mounted on the printed circuit board carried to the parts mounting work position by the head unit, the supply and discharge speed of the printed circuit board is decreased, thereby degrading the productivity of a parts mounting work of the surface mounting device.

### SUMMARY OF THE INVENTION

It is, therefore, an object of the present invention to provide a surface mounting device in which a plurality of conveyors for carrying a printed circuit board into a parts mounting position are provided and a multi-layer transfer for supplying the printed circuit board or storing the printed circuit board discharged by the conveyor is provided, thereby improving a speed for supplying and discharging a printed circuit board.

It is another object of the present invention to provide a surface mounting method for improving a speed of supplying and discharging the printed circuit board by possessing the plurality of multi-layer conveyors and transfers and enhancing a mounting work speed of parts by mounting the parts in the plurality of conveyors simultaneously.

To achieve the above object, there is provided a surface mounting device comprising: a plurality of conveyers installed at a predetermined position of a base frame and carrying a printed circuit board to a parts mounting work position or discharging the printed circuit board on which parts have been mounted, so that they can be moved in the X and Y-axis directions by a X-Y gantry installed on the base frame and can absorb parts supplied from a parts supply unit and the parts can be mounted by a head unit mounting the adsorbed parts on the printed circuit board; and a plurality of multi-layer transfer units each installed at both ends of the plurality of conveyers and carrying the printed circuit board to the plurality of conveyers or loading the discharged printed circuit board.

In addition, there is provided a surface mounting method comprising the steps of: carrying a printed circuit board loaded to a first multi-layer transfer unit into a first conveyor under control of a controller; discharging the printed circuit board carried to the first conveyor to a second multi-layer transfer unit under control of the controller; carrying the printed circuit board discharged to the second multi-layer transfer unit to a second conveyor under control of the controller; and discharging the printed circuit board carried to the second conveyor to the first multi-layer transfer unit under control of the controller.

### BRIEF DESCRIPTION OF THE DRAWINGS

The above objects, features and advantages of the present invention will become more apparent from the following detailed description when taken in conjunction with the accompanying drawings, in which:

FIG. 1 is a perspective view of a surface mounting device according to the conventional art;

FIG. 2 is a plane view of a surface mounting device schematically showing the internal construction of the surface mounting device as illustrated in FIG. 1;

FIG. 3 is a plane view of a surface mounting device according to the present invention;

FIG. 4 is a perspective view of a conveyer and a multi-layer transfer as illustrated in FIG. 3; and

FIGS. 5a through 5c are views showing a surface mounting method of parts using the surface mounting device as illustrated in FIG. 3.

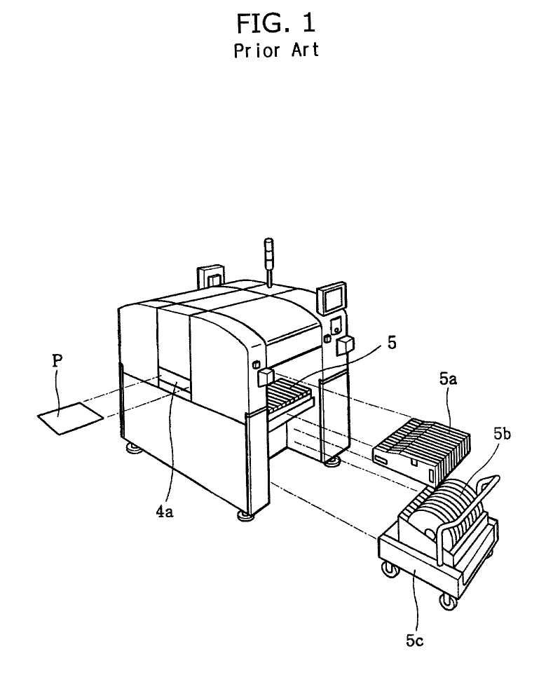

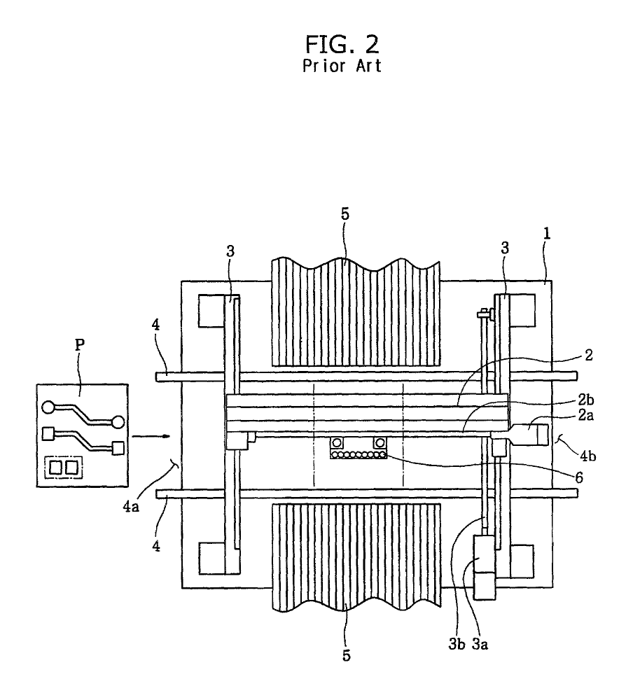

### DETAILED DESCRIPTION OF THE PREFERRED EMBODIMENT

A preferred embodiment of the present invention will now be described with reference to the accompanying drawings.

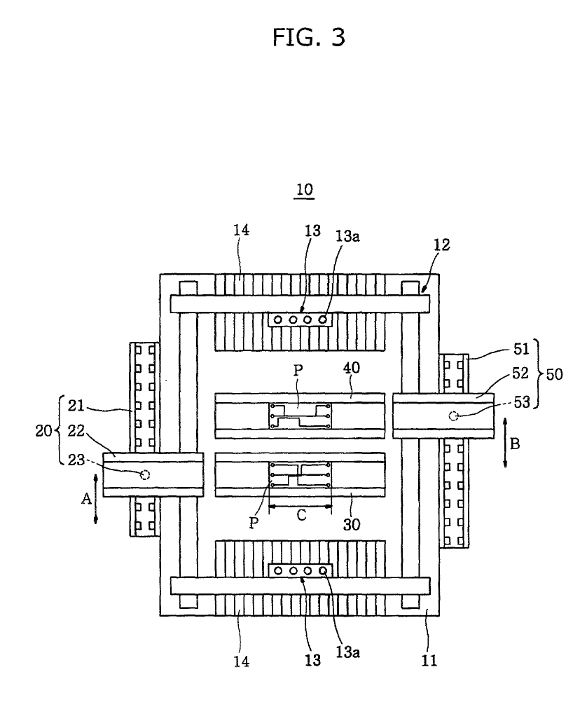

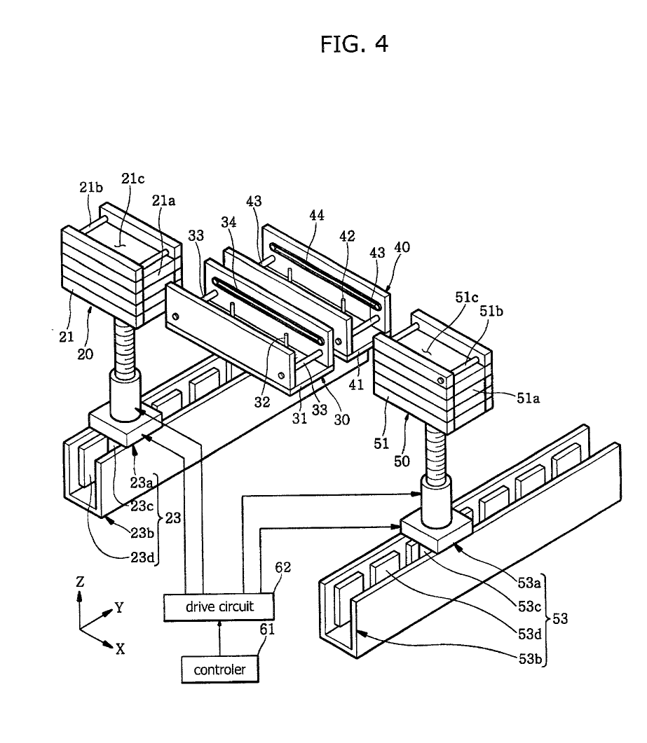

FIG. 3 is a plane view of a surface mounting device according to the present invention. FIG. 4 is a perspective view of a conveyer and a multi-layer transfer as illustrated in FIG. 3. As illustrated therein, the surface mounting device includes: a plurality of conveyers 30 and 40 installed at a predetermined position of a base frame 11 and carrying a printed circuit board (P) to a parts mounting work position or discharging the printed circuit board (P) on which parts have been mounted, so that they can be moved in the X and Y-axis directions by a X-Y gantry 12 installed on the base frame 11 and can absorb parts (not shown) supplied from a parts supply unit 14 and the parts can be mounted by a head unit 13 mounting the adsorbed parts on the printed circuit board (P); and a plurality of multi-layer transfer units 20 and 50 each installed at both ends of the plurality of conveyers 30 and 40 and carrying the printed circuit board (P) to the plurality of conveyers 30 and 40 or loading the discharged printed circuit board (P).

The construction and operation of the present invention will now be described in more detail.

As illustrated in FIG. 3, the surface mounting device 10 of the present invention is constructed in such a manner that the X-Y gantry 12, the head unit 13, the parts supply unit 14 and the plurality of conveyers 30 and 40 are installed on the base frame 11 and the plurality of multi-layer transfer units 20 and 50 are installed at both ends of the plurality of conveyers 30 and 40. Since the construction and operation of the X-Y gantry 12 installed on the base frame 11, the head unit 13 provided with a plurality of heads 13a and the parts supply unit 14 are identical to those according to the conventional art, so a detailed description thereof will be omitted. Now, the construction and operation of the present invention will be explained laying stress on the plurality of conveyers 30 and 40 for carrying or discharging the printed circuit board (P) to a parts mounting work position (a position of the printed circuit board at which the head unit 13 mounts parts) and the plurality of multi-layer transfer units 20 and 50.

The plurality of conveyers 30 and 40 are installed in parallel at a predetermined interval from each other at a predetermined position inside the X-Y gantry 12 installed on the base frame 11 and carry the printed circuit board (P) to the parts mounting work position or discharge the printed circuit board (P) on which parts have been mounted. To carry the printed circuit board (P) to the plurality of conveyers 30 and 40 or load the printed circuit board (P) discharged from the plurality of conveyers 30 and 40, the plurality of multi-layer transfer units 20 and 50 are installed at both ends of the plurality of conveyers 30 and 40.

The plurality of conveyers 30 and 40 includes a first conveyer 30 and a second conveyer 40, which carry the printed circuit board (P) carried from the plurality of multi-layer transfer units 20 and 50 to mount parts by the head unit 13 or discharge the printed circuit board (P) to the plurality of multi-layer transfer units 20 and 50 in a state that parts are not mounted.

The first conveyer 30 is installed at a predetermined position of the base frame 11 and carries the printed circuit board supplied from the plurality of multi-layer transfer units 20 and 50 to a parts mounting work position or discharges the printed circuit board (P) on which parts have been mounted. The second conveyer 40 is installed in parallel at a predetermined interval from the first conveyer 30 receiving the printed circuit board (P) from the plurality of multilayer transfer units 20 and 50 or discharging the same to the plurality of multi-layer transfer units 20 and 50. Like the first conveyer 30, the second conveyer 40 is also installed at a predetermined position of the base frame 11 and carries the printed circuit board supplied from the plurality of multi-layer transfer units 20 and 50 to a parts mounting work position or discharges the printed circuit board (P) on which parts have been mounted.

The construction of the first conveyer 30 and second conveyer 40 receiving the plurality of multilayer transfer units 20 and 50 and the printed circuit board (P) and discharging the same will now be described in more detail with reference to FIG. 4.

Firstly, the first conveyer 30 includes a first conveyer guide frame 31, a first conveyer lifting member 32, a first conveyer width adjusting roller 33 and a first conveyer driving unit 34. The first conveyer guide frame 31 is installed in such a manner that one side wall is moved along the first-conveyer width adjusting roller 33 and guides the printed circuit board (P) by varying the width of the first conveyer guide frame 31 according to the width of the printed circuit board (P). On the bottom of the first conveyer guide frame 31 of which the width is adjusted for guiding the printed circuit board (P), a plurality of first conveyer lifting members 32 are installed for lifting the printed circuit board (P) at a predetermined height so that parts can be mounted on the printed circuit board (P: shown in FIG. 3) by the head unit (13: shown in FIG. 3) and then lowering the printed circuit board (P) at the lifted height for discharging the same.

To carry the printed circuit board (P) carried from the plurality of multi-layer transfer units 20 and 50 to a parts mounting work position or carry or discharge the printed circuit board (P) on which parts are mounted or are not mounted, the first conveyer driving unit 34 is installed on an inner wall of the first conveyer guide frame 31. The first conveyer driving unit 34 is provided with a rotating motor (not shown), and carries the printed circuit board (P) according to a rotation force generated from the rotating motor and discharges the same to the parts mounting work position or to the plurality of multi-layer transfer units 20 and 50.

The second conveyer 40 is installed in parallel at a predetermined interval from the first conveyer 30 carrying or discharging the printed circuit board (P) to the parts mounting work position or to the plurality of multi-layer transfer units 20 and 50 and includes a second conveyer guide frame 41, a second conveyer lifting member 42, a second conveyer width adjusting roller 43 and a second conveyer driving unit 44. The construction and operation of the second conveyer 40 will be omitted since its is identical to the first conveyer 31.

The printed circuit boar (P) is carried, i.e., supplied, to the first and second conveyers 30 and 40 or the printed circuit board (P) discharged from the first and second conveyers 30 and 40 is discharged from the plurality of multi-layer transfer units 20 and 50 and is loaded. The plurality of multi-layer transfer units 20 and 50 supplying the printed circuit board (P) or loading the discharged printed circuit board (P) includes a first transfer unit 20 and a second transfer unit 50.

The first multi-layer transfer unit 20 is installed at one end of the plurality of first and second conveyers 30 and 40 and carries the printed circuit board (P) to the plurality of first and second conveyers 30 and 40 or loads the discharged printed circuit board (P). The second multi-layer transfer unit 50 is installed at the other end of the plurality of first and second conveyers 30 and 40 and carries the printed circuit board (P) to the plurality of first and second conveyers 30 and 40 or loads the discharged printed circuit board (P).

The first multi-layer transfer unit 20 carrying the printed circuit board (P) to the first and second conveyers 30 and 40 or loading the printed circuit board (P) discharged from the first and second conveyers 30 and 40 includes a plurality of first transfers 21, a first lifting device 22 and a first horizontal driving device 23.

The plurality of first transfers 21 are stacked in a vertical direction in order to carry the printed circuit board (P) to the first and second conveyers 30 and 40 or load the printed circuit board (P) discharged from the plurality of first and second conveyers 30 and 40. In the state that the plurality of first transfers 21 are stacked, the plurality of first transfers 21 are lifted and lowered in a vertical direction by the first lifting device 22 in order to carry the printed circuit board (P) to the plurality of first and second conveyers 30 and 40 or load the discharged printed circuit board (P).

The first lifting device 22 is installed on the bottom of the plurality of first transfers 21 stacked in the vertical direction, and it lifts and lowers each of the first transfers 21 in the vertical direction so that they can be arranged at the height of the plurality of first and second conveyers 30 and 40. To lift and lower the plurality of first transfers 21 in the vertical direction, one of a ball screw driving device, a timing belt driving device and a linear motor is selected and adapted as the first lifting device 22.

The plurality of transfers 21 and 51 lifted and lowered in the vertical direction to be arranged in the height of the plurality of first and second conveyers 30 and 40 by the first lifting device 22 are moved in a horizontal direction so that they can be arranged in the width of the plurality of first and second conveyers 30 and 40 with the vertical height of the plurality of first and second conveyers 30 and 40. To move the plurality of transfers 21 and 51 in the horizontal direction so that they can be arranged in the width of the plurality of first and second conveyers 30 and 40, a first horizontal driving device 23 is installed on the bottom of the first lifting device 22.

As the first horizontal driving device 23, a linear motor can be used as shown in FIG. 4 in order to move the plurality of first transfers 21 in the horizontal direction so that the plurality of first transfers 21 can be arranged in the width of one end of the plurality of first and second conveyers 30 and 40. Besides the linear motor, one of a ball screw driving device and a timing belt driving device can be selected and adapted.

As shown in FIG. 4, in a case that the linear motor is adapted as the first horizontal driving device 23, the linear motor as shown in FIG. 4 is a coil mover type linear motor. The coil mover type linear motor includes a mover 23a with an armature coil 23c and a stator 23b with a plurality of permanent magnets 23d arranged. The first lifting device 22 is installed at a predetermined position of the top surface of the mover 23a to be moved in the horizontal direction along with the plurality of first transfers when the plurality of first transfers 21 are moved in the horizontal direction. Here, the coil mover type linear motor moving the plurality of first transfers 21 in the horizontal direction can be replaced by a permanent magnet mover type linear motor.

The plurality of first transfers 21 moved in the vertical and horizontal directions by the first lifting device 22 and the first horizontal driving device 23 have to move the printed circuit board (P) in order to carry the loaded printed circuit board (P) to the plurality of first and second conveyers 30 and 40 or load the printed circuit board (P) discharged from each of the first and second conveyers 30 and 40. To move the printed circuit board (P), the plurality of first transfers 21 each include a first transfer guide frame 21a, a plurality of first transfer rollers 21b and a first belt member 21c.

The first transfer guide frame 21a is fixedly installed at another first transfer guide frame 21a for guiding or loading the printed circuit board (P) so that the plurality of first transfers 21 can be stacked and fixed in the vertical direction. To move the loaded or discharged printed circuit board (P) at a predetermined distance and then carry or load the same, a plurality of first transfer rollers 21b are installed at both side walls of the first transfer guide frame 21a at a predetermined interval.

The first transfer roller 21b is rotated by receiving the rotation force generated from a rotating motor (not shown) at the movement of the printed circuit boar (P) and drives the first belt member 21c installed between the plurality of first transfer rollers 21b. By driving the first belt member 21c by the plurality of first transfer rollers 21b, the printed circuit boar (P) mounted and loaded on the first belt member 21c can be carried to the plurality of first and second conveyers 30 and 40 and the printed circuit board (P) discharged from the plurality of first and second conveyers 30 and 40 can be loaded and stored.

Like the first multi-layer transfer unit 20 installed at one end of the plurality of first and second conveyers 30 and 40 for supplying or receiving the printed circuit board to/from the plurality of first and second conveyers 30 and 40, a second multi-layer transfer unit 50 is installed at the other end of the plurality of first and second conveyers 30 and 40. The second multi-layer transfer unit 50 supplies the printed circuit board (P) to the plurality of first and second conveyers 30 and 40, or loads the printed circuit board (P) discharged from the plurality of first and second conveyers 30 and 40.

As illustrated in FIG. 4, the second multi-layer transfer unit 50 includes a plurality of second transfers 51, a second lifting device 52 and a second horizontal driving device 53. In a case that a coil mover type linear motor is adapted as the second horizontal driving device 53, the linear motor includes a mover 53a with an armature coil 53c and a stator 53b with a plurality of permanent magnets 53d arranged. The plurality of second transfers 51 each include a second transfer guide frame 51a, a plurality of second transfer rollers 51b and a second belt member 51c. Here, since the construction and operation of the second multi-layer transfer unit 50 is identical to those of the first multi-layer transfer unit 20, a detailed description thereof will be omitted.

In this way, the first and second multi-layer transfer units 20 and 50 are moved in the vertical and horizontal directions, respectively, so that a plurality of printed circuit boards (P) each can be stored and loaded on the first and second multi-layer transfer units 20 and 50. In addition, by possessing the plurality of first and second conveyers 30 and 40, a large amount of printed circuit boards (P) are supplied and discharged continuously within a short time, for thereby improving the transfer speed of the printed circuit board (P).

There will now be explained a parts mounting method using the surface mounting device provided with a plurality of first and second multi-layer transfer units 20 and 50 and a plurality of first and second conveyers 30 and 40 in order to improve the transfer speed of the printed circuit board (P).

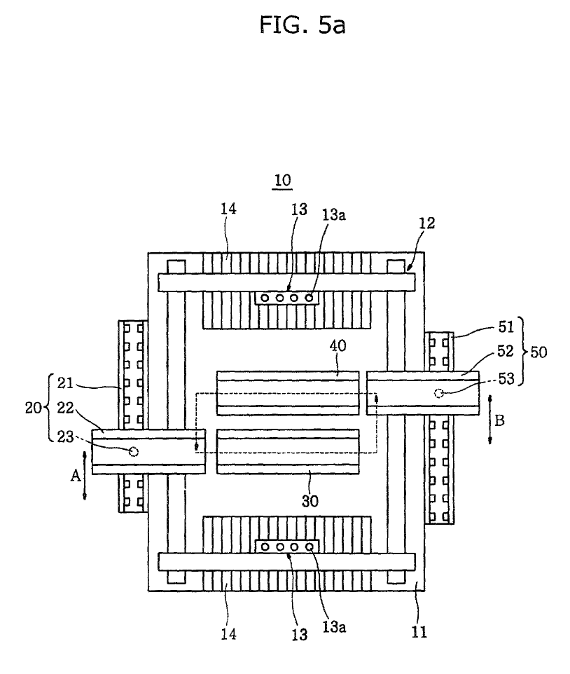

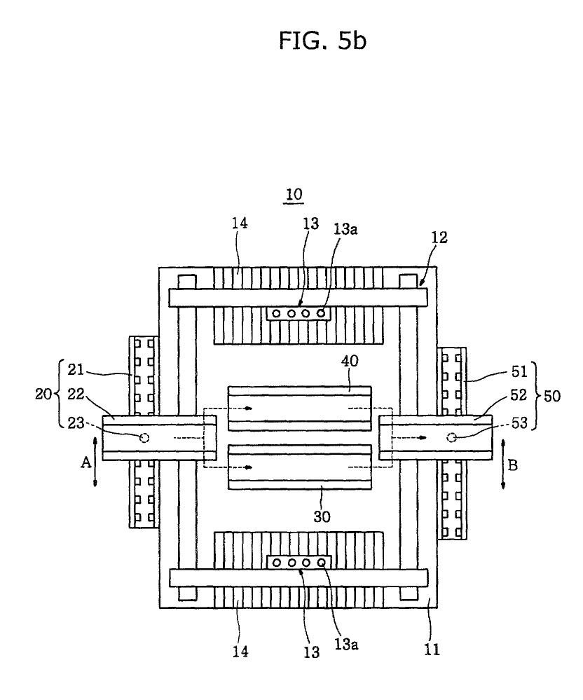

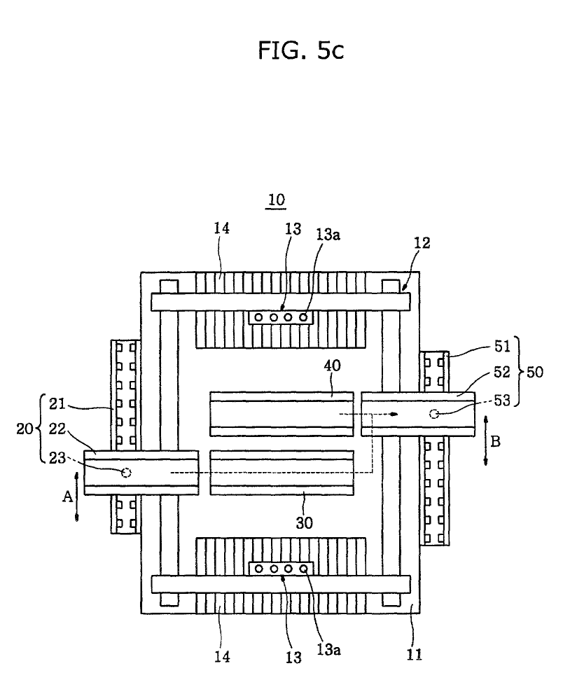

As the method of surface mounting parts according to the present invention, as illustrated in FIG. 5, a method of mounting parts by carrying a printed circuit board (P) by a closed loop method will now be explained.

Firstly, the step of carrying the printed circuit board (P) loaded at a predetermined position of the first multi-layer transfer unit 20 in an arrow direction shown in dotted lines under control of a controller 61 is performed. When the printed circuit board (P) is carried to the first conveyer 30, the step of discharging the carried printed circuit board (P) to the second multi-layer transfer unit 50 under control of the controller is performed. Next, the step of carrying the printed circuit board (P) discharged to the second multi-layer transfer unit 50 into the second conveyer 40 under control of the controller 61 is performed. Then, the step of discharging the printed circuit board (P) carried to the second conveyer 40 into the first multilayer transfer unit 20 under control of the controller 61 is performed for moving the printed circuit board (P) in the closed loop direction as shown in the arrow direction shown in dotted lines, thus mounting parts on the printed circuit board (P).

The controller 61 generally controls the surface mounting device 10 by generating a driving signal through a drive circuit 62 when controlling the transfer direction of the printed circuit board (P) by the controller 61. In addition, it can control the transfer direction of the printed circuit board (P) in the closed loop direction by programming the controller 61 previously. After the printed circuit board (P) is supplied from the first multi-layer transfer unit 20 to the second conveyer 40 under control of the controller 61, the printed circuit board (P) can be discharged to the second multi-layer transfer unit 50 from the second conveyer 40 by the plurality of heads 13a provided at the head unit 13 in a state that parts are mounted or are not mounted. In addition, the printed circuit board (P) can be discharged after parts are mounted by the head unit 13 driven by control of the controller 61 prior to discharging the printed circuit board (P) to the first multi-layer transfer unit 20 from the second conveyer 40, or it can be discharged in a state that parts are not mounted.

The first and second conveyers 30 and 40 can mount parts on the printed circuit board (P) or can carry parts without mounting them under control of the controller 61 by programming the controller 61 previously. In this way, as the first and second conveyers 30 and 40 can mount parts selectively or simultaneously, the parts mounting speed of the printed circuit boar (P) can be improved. That is, the parts mounting speed can be improved by mounting parts by the second conveyer 40 simultaneously when parts are mounted by the first conveyer 30 or by receiving or discharging the printed circuit board by one of the conveyers while parts are mounted on the printed circuit board (P) by the other conveyer.

Another method of surface mounting parts for improving the speed of mounting parts on the printed circuit board (P) can be explained with reference to FIGS. 5b and 5c.

As illustrated in FIGS. 5b and 5c, in another method of surface mounting parts of the present invention, firstly, the step of carrying the printed circuit board (P) loaded on the first multi-layer transfer unit 20 to the first and second conveyers 30 and 40 alternately under control of the controller is performed by an open loop method as shown in an arrow direction shown in dotted lines. When the printed circuit board (P) is carried to the first and second conveyers 30 and 40, parts are mounted on the printed circuit board (P) by the head unit 13. When parts mounting is finished, the step of discharging and loading the printed circuit board (P) disposed at the first and second conveyers 30 and 40 alternately onto the second multi-layer transfer unit 50 under control of the controller 61 is performed. When the printed circuit board (P) is discharged from the first and second conveyers 30 and 40 alternately, the step of loading and storing the printed circuit board (P) discharged from the second multi-layer transfer unit 50 is performed.

In the step of carrying the printed circuit board (P) loaded on the first multi-layer transfer unit 20 to the first and second conveyers 30 and 40 under control of the controller 61, the printed circuit board (P) loaded on the first multi-layer transfer unit 20 is carried to the first conveyer 30 under control of the controller 61, and then is carried to the second conveyer 40 after a predetermined time, for thereby adding flexibility to the supply of the printed circuit board (P) and mounting parts on the printed circuit board (P).

As seen from above, the surface mounting device of the present invention improves the transfer speed of a printed circuit board by possessing a plurality of multi-layer transfers and a plurality of conveyers and carrying a plurality of printed circuit boards simultaneously. In addition, the surface mounting speed can be improved by mounting parts on the printed circuit board simultaneously by a plurality of conveyers.

As described above, according to the present invention, there are several advantages that the surface mounting device of the present invention improves the transfer speed of a printed circuit board by possessing a plurality of multi-layer transfers and a plurality of conveyers and carrying a plurality of printed circuit boards simultaneously and in addition, the surface mounting speed can be improved by mounting parts on the printed circuit board simultaneously by a plurality of conveyers.

What is claimed is:

1. A surface mounting device comprising:
a plurality of conveyers installed at a predetermined position of a base frame and carrying a printed circuit board to a parts mounting work position or discharging the printed circuit board on which parts have been mounted, so that they can be moved in the X and Y-axis directions by a X-Y gantry installed on the base frame and can absorb parts supplied from a parts supply unit and the parts can be mounted by a head unit mounting the adsorbed parts on the printed circuit board; and
a plurality of multi-layer transfer units each installed at both ends of the plurality of conveyers and carrying the printed circuit board to the plurality of conveyers or loading the discharged printed circuit board.

2. The surface mounting device of claim 1, wherein the plurality of conveyors comprise a first conveyer installed at a predetermined position of the base frame and for carrying the printed circuit board supplied from the plurality of multi-layer transfer units to a parts mounting work position or discharging the printed circuit board on which parts have been mounted; and
a second conveyer installed at a predetermined position of the base frame and for carrying the printed circuit board supplied from the plurality of multi-layer transfer units to a parts mounting work position or discharging the printed circuit board on which parts have been mounted.

3. The surface mounting device of claim 2, wherein the first conveyor comprises a first conveyor guide frame for guiding the printed circuit board;
a plurality of first conveyor width adjusting rollers installed to the first conveyor guide frame at a predetermined position, respectively, and for guiding the first conveyor guide frame when controlling the width of the first guide frame;
a first conveyor lifting member installed to the inside of the first conveyor guide frame so that parts can be mounted on the printed circuit board or the printed circuit board can be lowered for discharging it; and
a plurality of conveyor driving units installed on an inner wall of the first conveyor guide frame so that the printed circuit board can be carried from the plurality of multi-layer transfer units carries to a parts mounting work position or the printed circuit board (P) on which parts are mounted can be discharged to the plurality of multi-layer transfer units.

4. The surface mounting device of claim 2, wherein the second conveyor comprises a second conveyor guide frame for guiding the printed circuit board;
a plurality of second conveyor width adjusting rollers installed to the second conveyor guide frame at a predetermined position, respectively, and for guiding the second conveyor guide frame when controlling the width of the second guide frame;
a second conveyor lifting member installed to the inside of the second conveyor guide frame so that parts can be mounted on the printed circuit board or the printed circuit board can be lowered for discharging it; and
a plurality of conveyor driving units installed on an inner wall of the second conveyor guide frame so that the printed circuit board can be carried from the plurality of multi-layer transfer units carries to a parts mounting work position or the printed circuit board (P) on which parts are mounted can be discharged to the plurality of multi-layer transfer units.

5. The surface mounting device of claim 1, wherein the plurality of multi-layer transfer units comprise a first multi-layer transfer unit installed at one end of the plurality of conveyers and for carrying the printed circuit board to the plurality of conveyers or loading the discharged printed circuit board; and
a second multi-layer transfer unit installed at the other end of the plurality of conveyers and for carrying the printed circuit board to the plurality of conveyers or loading the discharged printed circuit board.

6. The surface mounting device of claim 5, wherein the first multi-layer transfer unit comprises a plurality of first transfers stacked in a vertical direction for carrying the printed circuit board to the plurality of conveyers or loading the printed circuit board discharged from the conveyers;
a first lifting device for lifting/lowering the plurality of first transfers in the vertical direction so that they can be arranged at the height of the plurality of conveyers; and
a first horizontal driving device in which the plurality of first transfers are moved in the horizontal direction so that the plurality of first transfers can be arranged in the width of one end of the plurality of conveyers.

7. The surface mounting device of claim 6, wherein the plurality of first transfers comprise a first transfer guide frame for guiding each printed circuit board;
a plurality of first transfer roller installed to the first transfer guide frame with a predetermined interval and rotated by receiving a rotation force generated from a rotating motor for moving the printed circuit board; and
a first belt member installed between the plurality of first transfer rollers and driven by the plurality of first transfer rollers, thereby carrying or loading the printed circuit board.

8. The surface mounting device of claim 6, wherein the first lifting device is any one of a ball screw driving device, a timing belt driving device, and a linear motor.

9. The surface mounting device of claim 6, wherein the first horizontal driving device is any one of a ball screw driving device, a timing belt driving device, and a linear motor.

10. The surface mounting device of claims 8 or 9, wherein the linear motor is any one of a coil mover and a permanent magnet mover.

11. The surface mounting device of claim 5, wherein the second multi-layer transfer units comprise a plurality of second transfers stacked in the vertical direction for carrying the printed circuit board to the plurality of conveyors or loading the printed circuit board discharged from the plurality of conveyors;
a second lifting device for lifting/lowering the plurality of second transfers in the vertical direction so that they can be arranged at the height of the plurality of conveyers; and
a second horizontal driving device in which the plurality of second transfers are moved in the horizontal direction so that the plurality of second transfers can be arranged in the width of one end of the plurality of conveyers.

12. The surface mounting device of claim 11, wherein the plurality of second transfers comprise a second transfer guide frame for guiding each printed circuit board;
a plurality of second transfer roller installed to the second transfer guide frame with a predetermined interval and rotated by receiving a rotation force generated from a rotating motor for moving the printed circuit board; and
a second belt member installed between the plurality of second transfer rollers and driven by the plurality of second transfer rollers, thereby carrying or loading the printed circuit board.

13. The surface mounting device of claim 11, wherein the second lifting device is any one of a ball screw driving device, a timing belt driving device, and a linear motor.

14. The surface mounting device of claim 11, wherein the second horizontal driving device is any one of a ball screw driving device, a timing belt driving device, and a linear motor.

15. The surface mounting device of claims 13 or 14, wherein the linear motor is any one of a coil mover and a permanent magnet mover.

16. The surface mounting method comprising the steps of:
carrying a printed circuit board loaded to a first multi-layer transfer unit into a first conveyor under control of a controller;
discharging the printed circuit board carried to the first conveyor to a second multi-layer transfer unit under control of the controller;
carrying the printed circuit board discharged to the second multi-layer transfer unit to a second conveyor under control of the controller; and
discharging the printed circuit board carried to the second conveyor to the first multi-layer transfer unit under control of the controller.

17. The surface mounting method of claim 16, wherein in the step of discharging the printed circuit board carried to the first conveyor to the second multilayer transfer unit under control of the controller, the printed circuit board can be discharged the second multi-layer transfer unit in a state that parts are mounted or not mounted under control of the controller.

18. The surface mounting method of claim 16, wherein in the step of discharging the printed circuit board carried to the second conveyor to the first multilayer transfer unit under control of the controller, the printed circuit board can be discharged the second multi-layer transfer unit in a state that parts are mounted or not mounted under control of the controller.

19. The surface mounting method comprising the steps of:
carrying alternately a printed circuit board loaded to a first multi-layer transfer unit to a first and a second conveyors under control of a controller; and
mounting parts on the printed circuit board by a head unit when the printed circuit board is carried to the first and second conveyers, discharging the printed circuit board disposed at the first and second conveyers alternately onto the second multi-layer transfer unit under control of the controller when parts mounting is finished, loading the printed circuit board discharged from the second multi-layer transfer unit when the printed circuit board is discharged from the first and second conveyers alternately.

20. The surface mounting method of claim 19, wherein in the step of carrying the printed circuit board loaded on the first multi-layer transfer unit to the first and second conveyers under control of the controller, the printed circuit board loaded on the first multi-layer transfer unit is carried to the first conveyer under control of the controller, and then is carried to the second conveyer after a predetermined time.
